(19) United States
(12) Patent Application Publication
(10) Pub. No.: US 2025/0171299 A1
(43) Pub. Date: May 29, 2025

(54) METHOD FOR MANUFACTURING A PACKAGING STRUCTURE

(71) Applicant: COMMISSARIAT A L'ENERGIE ATOMIQUE ET AUX ENERGIES ALTERNATIVES, Paris (FR)

(72) Inventor: Audrey BERTHELOT, Grenoble Cedex 09 (FR)

(73) Assignee: COMMISSARIAT A L'ENERGIE ATOMIQUE ET AUX ENERGIES ALTERNATIVES, Paris (FR)

(21) Appl. No.: 18/946,498

(22) Filed: Nov. 13, 2024

(30) Foreign Application Priority Data
Nov. 23, 2023 (FR) 2312944

(51) Int. Cl. B81C 1/00; B81B 7/00

(52) U.S. Cl. CPC B81C 1/00285; B81B 7/0038; B81B 2201/0235; B81B 2201/0242; B81B 2203/0315; B81C 2201/013; B81C 2201/0181; B81C 2203/019; B81C 2203/037

(57) ABSTRACT

The invention relates to a method for manufacturing a packaging structure 1 comprising a first cavity 300a and a second cavity 300b, both hermetic. The method includes a step of forming over a substrate 100 a first portion 105a of a material capable of releasing a noble gas contained in the material by heating, intended to form a wall of the first cavity 300a; a step of sealing the substrate 100 to a cover 200 to form and hermetically close each of the first and second cavities 300a, 300b; a step of heating the first and second cavities 300a, 300b to release the noble gas contained in the material. The first portion 105a contributes to sealing of the substrate 100 to the cover 200 during the sealing step.

### TECHNICAL FIELD

The field of the invention relates to packaging of a microelectronic device, such as a micro-electro-mechanical system (MEMS, or “Micro-Electro Mechanical System” in English), or a micro-opto-electro-mechanical system (MOEMS, or “Micro-Opto-Electro Mechanical System” in English), or a nano-electro-mechanical system (NEMS, or “Nano-Electro Mechanical System” in English), or a nano-opto-electro-mechanical system (NOEMS, or “Nano-Opto-Electro Mechanical System” in English). In particular, the invention relates to the collective packaging of microelectronic devices in at least one cavity with a controlled pressure.

### PRIOR ART

In general, microelectronics devices are packaged to protect them from elements that might damage them, like humidity, particle pollution, a reactive gas such as oxygen, etc. Some microelectronics devices should also be hermetically packaged in a cavity at a predetermined pressure and/or containing a particular gas.

For example, a MEMS-type gyroscope should be hermetically packaged at a pressure lower than 10⁻¹ mbar, and possibly lower than 10⁻⁴ mbar. In general, a MEMS-type radio-frequency switch is hermetically packaged in a neutral gaseous environment, at the atmospheric pressure, to avoid oxidation of contact areas of the switch. Typically, a MEMS-type accelerometer measures the displacement of a mass subjected to an acceleration. The mass is a portion of a suspended structure. To obtain an accurate measurement of the acceleration, the set should be damped by a gas pressure in a cavity in which the accelerometer is hermetically packaged. For example, the pressure is at least higher than 1 mbar. The pressure allows controlling a damping factor of the suspended structure and/or of the mass.

There are two alternative techniques for hermetically packaging a microelectronic device made over and/or in a substrate.

According to a first method, a thin layer is deposited over a structured sacrificial layer trapping the device, and over the substrate. The thin layer has a thickness typically comprised between 0.1 μm and 5 μm. At least one through vent is formed throughout the thin layer. Afterwards, the sacrificial layer is etched and evacuated throughout the vent. Afterwards, the vent is plugged by deposition of a material under vacuum, for example by evaporation or by physical vapor deposition. The device is then packaged in a cavity under vacuum delimited by a cover consisting of the thin layer and by the substrate. This method has some advantages, like a good compactness, a good transmission of an electromagnetic radiation through the cover, etc.

However, a second method is often preferred, which method is more robust and less constraining with regards to the selection of the materials, or thermal budget, or for other aspects. It includes an hermetic sealing of a cover having a thickness comprised between 10 μm and a few hundred micrometers, for example comprised between 300 μm and 750 μm, or between 300 am and 400 μm, over the substrate, so as to trap the device in a cavity delimited by the cover and the substrate. Sealing may be carried out by different techniques among which, mention may be made of: molecular bonding, metallic bonding, anodic sealing, and sintered glass sealing.

An example of a method for manufacturing a packaging structure according to the second method is disclosed in document WO2015/119564. The latter allows hermetically packaging several devices of the same chip, each in a distinct hermetic cavity, with a controlled internal pressure. Voids are formed in a cover. Each is intended to delimit one cavity. Afterwards, a structural element is formed in a void. The structural element comprises ions, atoms or molecules of a gas, which are trapped, absorbed or adsorbed. The cover is sealed under vacuum to a substrate comprising microelectronic devices so as to trap each device in a distinct cavity. Thus, the packaging structure is obtained. A subsequent heating allows releasing the gas of the structural element in the cavity containing it, thus a pressure higher than the pressure of the sealing step could be obtained in this cavity.

In FIGS. 9 and 10 of document WO2015/119564, the structural element may be a metal obtained by physical vapor deposition using argon as a carrier gas. The metal then contains argon. The latter is released in the cavity by heating taking place after sealing. Thus, a predetermined pressure could be obtained in the cavity. It is possible to reach two different pressures in two distinct cavities by depositing two different structural elements made of metal in two distinct voids of the cover, during two distinct deposition steps leading to a different argon concentration in one structural element compared to another.

However, the manufacturing method of document WO2015/119564 is complex to implement, involves many steps and leads to a quite large packaging structure.

### DESCRIPTION OF THE INVENTION

An objective of the invention is to overcome at least part of the drawbacks of the prior art, and more particularly provide a simplified method for manufacturing a packaging structure comprising at least two hermetic cavities. The manufacturing method results in a packaging structure which is more compact than the prior art.

For this purpose, an object of the invention is a method for manufacturing a packaging structure comprising a first cavity and a second cavity, both hermetic, the method including a step of forming over a substrate a first portion of a material capable of releasing a noble gas contained in the material by heating, intended to form a wall of the first cavity; a step of sealing the substrate to a cover so as to form and hermetically close each of the first and second cavities; a step of heating the first and second cavities to release the noble gas contained in the material. The method is such that the first portion contributes to sealing of the substrate to the cover during the sealing step.

Some preferred, yet non-limiting, aspects of this manufacturing method are as follows.

The sealing step may be carried out using an eutectic alloy or by thermocompression, and may comprise the heating step.

The sealing step may be performed under a high vacuum at a pressure lower than 0.1 Pa, preferably lower than 0.001 Pa.

The step of forming the first portion may comprise a PVD or IBD type deposition in the presence of a carrier gas of the same nature as the noble gas.

A second portion of the material may be formed over the substrate or over the cover so that the second portion forms a wall of the second cavity, the second portion contributing to sealing of the substrate to the cover during the sealing step.

The second portion may be formed over the substrate, at the same time as the first portion during the formation step.

The wall of the first cavity formed by the first portion may have a first surface relative to the volume of the first cavity strictly greater than a second surface of the wall of the second cavity formed by the second portion relative to the volume of the second cavity.

The manufacturing method may further comprise a step of forming a portion of a non-evaporable getter-type material over the substrate or the cover, intended to form a wall of the second cavity, and the getter material portion may be activated during the heating step.

The packaging structure may further comprise a third hermetic cavity, wherein a third portion of the material may be formed over the substrate, at the same time as the first portion and the second portion during the formation step, so that the third portion forms a wall of the third cavity having a third surface strictly comprised between the first surface and the second surface, the third portion possibly contributing to sealing of the substrate to the cover during the sealing step.

The material may be selected from among germanium, gold, an aluminum and silicon alloy and an aluminum and copper alloy.

The manufacturing method may further comprise, prior to the sealing step, a step of digging a void in the substrate and/or the cover intended to form walls of the first and/or second cavity.

The manufacturing method may further comprise, prior to the sealing step, a step of making a first microelectronic device in and/or over the substrate and/or the cover intended to be trapped in the first cavity, and a step of making a second microelectronic device in and/or over the substrate and/or the cover intended to be in the second cavity.

The first microelectronic device may be an accelerometer and the second microelectronic device may be a gyroscope.

The manufacturing method may further comprise, prior to the sealing step, a step of making an accelerometer in and/or over the substrate and/or the cover intended to be trapped in the third cavity.

### BRIEF DESCRIPTION OF THE DRAWINGS

Other aspects, aims, advantages and features of the invention will appear better upon reading the following detailed description of preferred embodiments thereof, given as a non-limiting example, and made with reference to the appended drawings wherein:

FIGS. 1A and 1B are schematic sectional views of steps of manufacture of microelectronic devices;

FIGS. 2A to 2C are schematic sectional views of steps of manufacture of a cover;

FIGS. 3A and 3B are schematic sectional views of steps of manufacture of a packaging structure;

FIGS. 4A to 4E are schematic sectional views of non-limiting examples of intermediate structures that could be implemented in the method of the invention.

### DETAILED DISCLOSURE OF PARTICULAR EMBODIMENTS

In the figures and in the following description, the same references represent identical or similar elements. In addition, the different elements are not plotted to scale so as to favor clarity of the figures. Moreover, the different embodiments and variants are not exclusive of one another and could be combined together. Unless stated otherwise, the terms “substantially”, “about”, “in the range of” mean within a 10% margin, and preferably within a 5% margin. Moreover, the terms “comprised between . . . and . . . ” and the like mean that the bounds are not included, unless stated otherwise.

The invention relates to a method for manufacturing a packaging structure comprising at least two cavities. The method comprises a step of sealing a substrate and a cover by at least one portion of a material including atoms of a noble gas, which could be trapped, absorbed or adsorbed by the material. The portion forms a wall of a cavity. A heating step, which may advantageously be a sub-step of sealing, allows releasing the noble gas through the wall formed by the portion in the cavity. The surface of the wall formed by the portion is selected so as to release a predetermined amount of the noble gas. Thus, the portion ensures at least three functions, namely sealing, delimitation of the cavity, as well as the definition of its volume, and the regulation of an internal pressure of the cavity, or the introduction of a particular noble gas. The packaging structure resulting from the method of the invention is then compact, and requires less process steps.

The method of the invention allows packaging several devices of the same plate at the same time before cutting into several independent electronic chips. In this case, it consists of a collective packaging method which could be an essential building block of a collective packaging method including for example electrical connections towards a PCB or another support. This collective packaging family is known by the acronym WLF, standing for “Wafer Level Packaging” in English.

Throughout the description, by noble gas, it should be understood a chemically-inert gas, i.e. it does not establish any covalent bond with other atoms. The elements of the group 18 of the periodic table of elements are examples of noble gases. For example, a noble gas that is satisfactory for the invention may be helium, neon, argon, krypton, xenon, radon, or a mixture of these gases.

Throughout the description, a cavity is a fully enclosed volume containing a gas, air or vacuum. The cavity is hermetic if a gas cannot escape or enter in the closed volume. The closed volume is delimited by walls of the cavity.

By layer, it should be understood an extended portion of a material whose thickness according to the Z axis is smaller, for example ten times, or twenty times, as small as its widthwise and lengthwise longitudinal dimensions in a plane (X, Y) perpendicular to the Z axis.

Particular embodiments will now be described, relating to a method for manufacturing a packaging structure including at least two cavities. However, these embodiments could be adapted to make any other structure trapping a gas in a hermetic cavity.

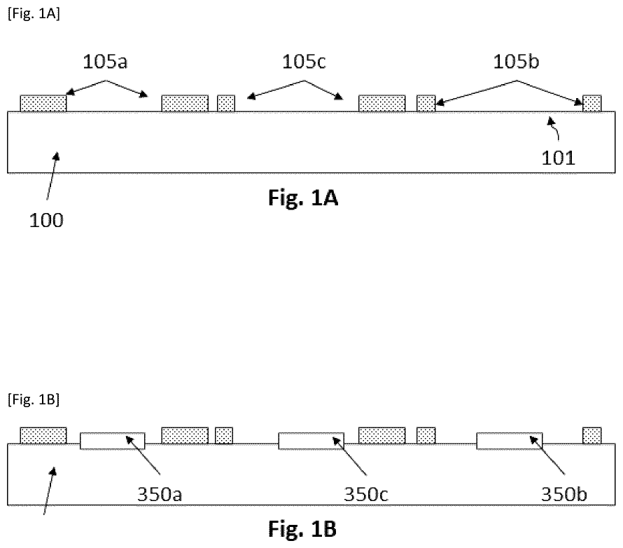

In FIG. 1A, a first layer of a material, so-called charged material, capable of releasing a noble gas by heating is deposited over a first face 101 of a substrate 100. In the figures, the presence of a noble gas in a layer or a portion is materialized by a hatch representing an array of points.

For example, the substrate 100 may be a plate, like a silicon-on-insulator type plate (or SOI, standing for “Silicon On Insulator”, in English), for example with a diameter of 150 mm, 200 mm or 300 mm. Alternatively or complementarily, the substrate 100 may comprise components of an electronic circuit, like transistors and/or metal interconnections. The charged material comprises ions, atoms or molecules of the noble gas, which could be trapped, absorbed or adsorbed. It is composed of a matrix and of the noble gas, i.e. it consists of the matrix and of the noble gas. The charged material comprises essentially a metal or a semiconductor. The presence of the noble gas in the charged material results from the implemented deposition method.

The substrate 100 is gas-impermeable. It has a thickness according to a direction perpendicular to the first face 101, comprised between 10 μm and a few hundred micrometers, for example comprised between 300 μm and 750 μm, or between 300 am and 400 μm. The charged material may comprise essentially gold, copper, titanium, aluminum, tin, silicon, germanium, an aluminum and silicon alloy, or an aluminum and copper alloy, or a mixture of these compounds.

In this case, and throughout the description, a material, a portion or a layer comprises essentially (respectively predominantly) one compound, if the material, the portion or the layer includes less than 10% (respectively less than 50%) of elements different from the compound and different from atoms of the noble gas of interest. A layer comprises essentially (respectively predominantly) a group of compounds or a mixture of compounds, if the material, the portion or the layer includes less than 10% (respectively less than 50%) of elements different from the group of compounds or the mixture of compounds and different from atoms of the noble gas of interest. In the case where a material is selected from among a group of compounds, it should be understood that the material comprises essentially the selected compound.

For example, the first layer is deposited in a chamber by physical vapor deposition (or PVD, standing for Physical Vapor Deposition in English) using a plasma comprising the metal or the semiconductor and a carrier gas of the same nature as the noble gas. For example, the carrier gas is helium, neon, argon, krypton, xenon, radon, or a mixture of these gases. Thus, noble gas atoms are trapped in the first layer. A pressure and/or a carrier gas concentration in the chamber allow adjusting an amount of noble gas atoms trapped in the charged material. For example, it is possible to deposit aluminum by PVD with a plasma of argon and/or krypton, in addition to aluminum. It is also possible to deposit gold by PVD with a plasma of argon and/or krypton and/or nitrogen, in addition to gold.

Alternatively, the first layer may be deposited by an ion beam deposition technique (IBD, standing for “Ion Beam Deposition” in English), or by ion beam sputtering (IBS, standing for “Ion Beam Sputtering” in English). These deposition techniques typically involve bombing a target including the metal or the semiconductor by a sputtering ion beam. The target and the substrate 100 are placed in a deposition chamber under vacuum. Optionally, an assist ion beam could intervene during the deposition. A neutralizer introducing a neutral gas into the chamber is often used to avoid insulating surfaces of the chamber or insulating elements located in the chamber being charged for example under the effect of the sputtering and assist ion beams. The sputtering, and where appropriate assist, ion beams may comprise atoms of a noble gas, like for example argon, krypton or xenon. The neutral gas of the neutralizer may consist of argon, which is a noble gas. Thus, at least one portion of the sputtering ion beam and/or the assist ion beam and/or of the neutral gas forms a carrier gas of the same nature as the noble gas, and noble gas atoms are trapped in the first layer. Parameters of the deposition allow adjusting an amount of noble gas atoms trapped in the charged material, like for example a pressure of the deposition chamber, angular orientations of the substrate 100, of the target, of the sputtering and assist ion beams, an energy of the sputtering and assist ion beams.

Afterwards, the first layer is locally etched, for example by dry etching throughout a mask, to make at least one first portion 105a. In this case, a second portion 105b and a third portion 105c are also made during this step. For example, the first layer is etched across its entire thickness to locally expose the first face 101 of the substrate 100. As shown in FIG. 1A, the first, second and third portions 105a, 105b, 105c may be dissociated, i.e. they are not in contact. Any one of the first, second and third portions 105a, 105b, 105c may also be in physical, i.e. joint, contact with another portion amongst the first, second and third portions 105a, 105b, 105c in a region intended to be an inter-cavity region 320 of the packaging structure 1, i.e. the first layer has not been etched in the inter-cavity region 320.

The first, second and third portions 105a, 105b, 105c are respectively intended to form walls of distinct first, second and third cavities 300a, 300b, 300c. In this example, the first, second and third portions 105a, 105b, 105c are formed at the same time, i.e. their respective formations result from the same steps of the method comprising the deposition and etching of the first layer.

In FIG. 1B, a first microelectronic device 350a, a second microelectronic device 350b and a third microelectronic device 350c are made in the substrate 100 and/or over the first face 101 of the substrate 100. Steps of making the first, second and third microelectronic devices 350a, 350b, 350c may comprise common sub-steps. Each microelectronic device amongst the first, second and third microelectronic devices 350a, 350b, 350c has a functional portion to be exposed to a gas pressure and/or to a particular gas. The functional portion of the first, second and third microelectronic device 350a, 350b, 350c is intended to be respectively exposed to the inside of the first, second and third cavities 300a, 300b, 300c.

In this case, the first portion 105a surrounds the first microelectronic device 350a in all directions of a plane substantially parallel to the first face 101 of the substrate. The second and third portions 105b, 105c respectively surround the second and third microelectronic devices 350b in all directions of the plane. Thus, the first, second and third portions 105a, 105b, 105c form beads, so-called sealing beads, respectively around the first, second and third microelectronic devices 350a, 350b, 350c.

In this example, the first microelectronic device 350a is an accelerometer and the third microelectronic device 350c is an additional accelerometer. The second microelectronic device 350b is a gyroscope.

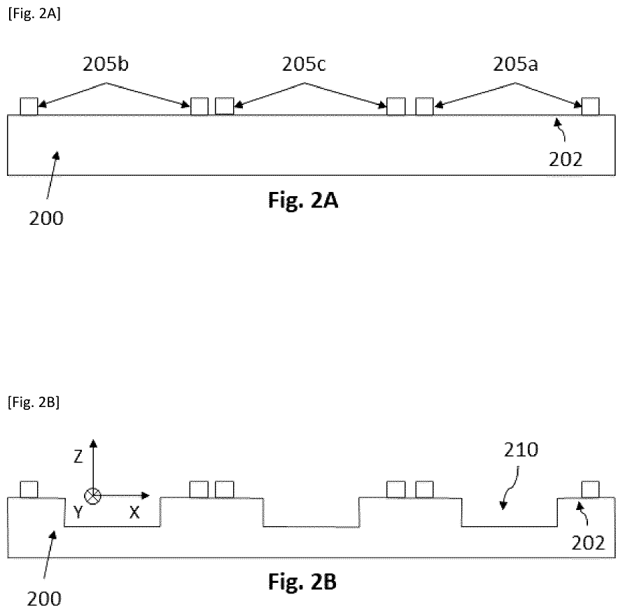

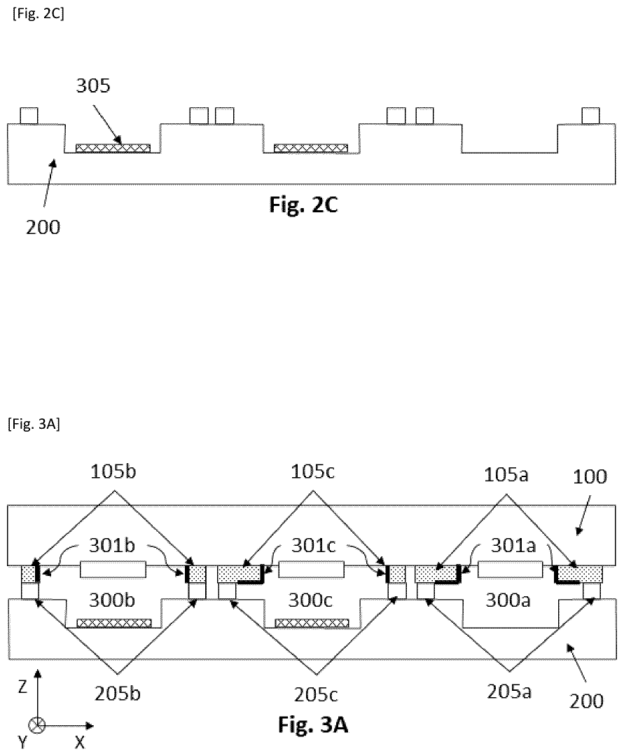

In FIG. 2A, a second layer made of a material, so-called complementary material, is deposited over a second face 202 of a cover 200. The complementary material is able to stick to, and/or merge with, and/or create an alloy with the charged material when it is brought into contact with the charged material, possibly with input from an external energy source, like a heating step, or the application of a mechanical force, or possibly both. The complementary material may be of the same nature as the matrix of the charged material or be the same as the charged material. The complementary material itself may be capable of releasing by heating an additional noble gas, identical to or different from the noble gas contained in the charged material. It could then be obtained by one of the deposition techniques that can be used to deposit the first layer.

The cover 200 is gas-impermeable, for example, it comprises essentially a semiconductor. It has a thickness according to a direction perpendicular to the second face 202, comprised between 10 μm and a few hundred micrometers, for example comprised between 300 μm and 750 μm, or between 300 am and 400 μm. In the case where the substrate 100 is a disk-like shaped plate, the cover 200 may, for example, be a disk-like shaped plate with the same diameter as the substrate 100. For example, the second layer may consist of gold, copper, titanium, aluminum, tin, silicon, germanium, an aluminum and silicon alloy, or an aluminum and copper alloy.

Afterwards, the second layer is locally etched, for example by dry etching throughout a mask, to make at least one first complementary portion 205a. In this case, a second complementary portion 205b and a third complementary portion 205c are also made during this step. For example, the second layer is etched across its entire thickness to locally expose the second face 202 of the cover 200. In this case, the first, second and third complementary portions 205a, 205b, 205c are positioned and sized so as to entirely rest, respectively, on the first, second and third portions 105a, 105b, 105c when the cover 200 is placed opposite the substrate 100.

Like for the first, second and third portions 105a, 105b, 105c, the first, second and third complementary portions 205a, 205b, 205c may be dissociate, as shown in FIG. 2A or joined together.

An orthogonal three-dimensional direct reference frame (X, Y, Z) is defined herein and for the following description, where the X and Y axes form a plane parallel to the main plane of the cover 200, and where the Z axis is directed substantially orthogonal to the main plane of the cover 200, from a face opposite to the second face 202, towards the second face 202. In the case where the cover is a plate including a mark in the form of a notch or a flat surface, the X axis is directed from the center of the plate towards the mark. In the following description, the terms “vertical” and “vertically” should be understood as relating to an orientation substantially parallel to the Z axis, and the terms “horizontal” and “horizontally” as relating to an orientation substantially parallel to the plane (X, Y). Moreover, the terms “lower” and “upper” should be understood as relating to an increasing positioning when getting away from the cover 200 according to the direction +Z.

In FIG. 2B, voids 210 are etched in the cover 200 which extend in the cover 200 from the second face 202 over a depth comprised for example between 5 μm and 500 μm. For example, it is possible to use KOH-based wet etching, or dry etching. Each void 210 is intended to be a wall of one amongst the first, second and third cavities 300a, 300b, 300c.

In this case, each first, second or third complementary portion 205a, 205b, 205c surrounds a void 210 in all directions of a plane substantially parallel to the plane (X, Y). Thus, the first, second and third complementary portions 205a, 205b, 205c form sealing beads, around a void 210.

In FIG. 2C, a portion of a non-evaporable getter material 305 is optionally formed on bottom of at least one void 210, through steps of deposition, photolithography and etching conventional in the microelectronics industry. In this case, two portions of a non-evaporable getter material 305 have been formed in two respective voids 210.

A non-evaporable getter material is a material that can capture chemically-active gas molecules by forming stable chemical bonds with the gas over a surface of the getter material. Chemically-active gases include for example: H₂, O₂, N₂, H₂O, CO and CO₂. The noble gases do not chemically react with the surface. Hence, they are not adsorbed by the getter material. The getter material may include one or more layer(s) each comprising predominantly titanium, zirconium or chromium, or a mixture of these materials.

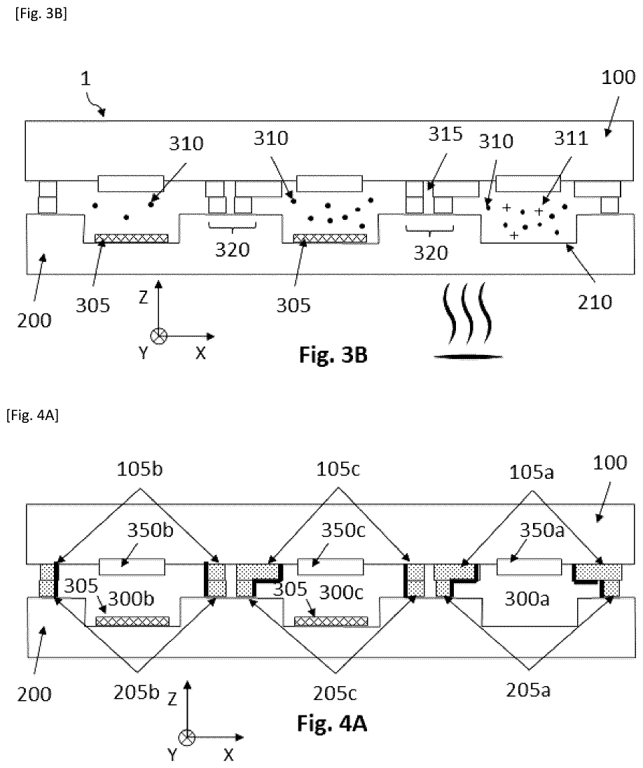

FIGS. 3A and 3B show a step of sealing in an enclosure under a high vacuum. The substrate 100 is affixed onto the cover 200 so as to bring the first, second and third portions 105a, 105b, 105c respectively into contact with the first, second and third complementary portions 205a, 205b, 205c. For example, a gas pressure in the enclosure is lower than 10⁻³ mbar (0.1 Pa), and possibly lower than 10⁻⁵ mbar (0.001 Pa) during the sealing step.

The first portion 105a and the second complementary portion 205a then close the first cavity 300a delimited by the first portion 105a, the first complementary portion 205a, the cover 200 and the substrate 100. A wall of the first cavity 300a is formed by one among voids 210. Similarly, the second portion 105b and the second complementary portion 205b closes the second cavity 300b delimited by the second portion 105b, the second complementary portion 205b, the cover 200 and the substrate 100. The third portion 105c and the third complementary portion 205c closes the third cavity 300c delimited by the third portion 105c, the third complementary portion 205c, the cover 200 and the substrate 100. The pressure inside the first, second and third cavities 300a, 300b, 300c is then substantially equal to the pressure of the enclosure.

A first surface 301a of the first portion 105a inside the first cavity 300a forms a wall of the first cavity 300a (in thick line in FIG. 3A). Similarly, a second surface 301b of the second portion 105b inside the second cavity 300b forms a wall of the second cavity 300b. And, a third surface 301c of the third portion 105c inside the third cavity 300c forms a wall of the third cavity 300c. The first, second and third portions 105a, 105b, 105c and the first, second and third complementary portions 205a, 205b, 205c are arranged and sized so that the first surface 301a is strictly larger than the third surface 301c, and that the third surface 301c is strictly larger than the second surface 301b.

In this example, each of the first and third surfaces 301a, 301c comprises a lower face, so-called overflow face, substantially planar and parallel to the plane (X, Y), surrounding a central region in which the first and third microelectronic devices 350a, 350c are respectively located. Each of the first and third surfaces 301a, 301c also comprises an inner face substantially orthogonal to the plane (X, Y) also surrounding the respective central region. The second surface 301b is devoid of any overflow, it therefore has a minimum surface area.

In this case and throughout the description, when two surfaces are compared with each other, this means that the surface areas of these surfaces are compared. Thus, by “the first surface 301a is strictly larger than the third surface 301c”, it should be understood that the surface area of the first surface 301a is strictly larger than the surface area of the third surface 301c.

An inter-cavity region 320 is defined as being a region external to the cavities, extending according to the Z axis between the first face 101 of the substrate 100 and the second face 202 of the cover 200, and according to a plane parallel to the plane (X, Y) between two inner walls of two contiguous cavities. In this example, an inter-cavity region 320 between the first cavity 300a and the third cavity 300c comprises a space 315 between, on the one hand, the first portion 105a and the first complementary portion 205a and, on the other hand, the third portion 105c and the third complementary portion 205c. This space 315 possibly allows dissociating a chip comprising the first microelectronic device 350a from another chip comprising the third microelectronic device 350c by cutting using a saw at the level of the space 315.

In FIG. 3B, heating at a temperature Tc allows hermetically sealing the first, second and third cavities 300a, 300b, 300c and releasing the noble gas 310, i.e. the temperature Tc is high enough to release at least part of the noble gas 310 of the charged material. The released amount of noble gas atoms increases with the surface of the wall formed by the charged material. Thus, since the first surface 301a is strictly larger than the third surface 301c, the amount of noble gas atoms 310 released in the first cavity 300a is strictly greater than the amount of noble gas atoms 310 released in the third surface 301c. Similarly, the amount of atoms in the third cavity 300c is strictly greater than the amount of noble gas atoms 310 of the second cavity 300b. In this case, the first, second and third cavities 300a, 300b, 300c have substantially equal volumes. Consequently, upon completion of heating, the partial pressure of the noble gas in the first cavity 300a is strictly higher than the partial pressure of the noble gas in the third cavity 300c, which is strictly higher than the partial pressure of the noble gas in the second cavity 300b.

The respective functional portions of the first, second and third microelectronic devices 350a, 350b, 350c are respectively exposed to the inside of the first, second and third cavities 300a, 300b, 300c, i.e. they are packaged or trapped in a distinct cavity amongst the first, second and third cavities 300a, 300b, 300c.

For example, the volume of the first, second and third cavities 300a, 300b, 300c is equal to 34·10⁶ μm³. The difference between the third surface 301c and the second surface 301b may be at least greater than 18·10³ m², or greater than 37·10³ m², preferably greater than 70·10³ m². Similarly, the difference between the second surface 301b and the third surface 301c may be at least greater than 18·10³ m², or greater than 37·10³ m², preferably greater than 70·10³ m². The first, second and third portions 105a, 105b, 105c and the first, second and third complementary portions 205a, 205b, 205c have thicknesses measured along the Z axis comprised between 10 nm and 5 μm, for example comprised between 100 nm and 1 μm, for example equal to 500 nm. For example, the thicknesses of the first, second and third portions 105a, 105b, 105c are substantially equal to a first common thickness. Similarly, the thicknesses of the first, second and third complementary portions 205a, 205b, 205c may be equal to a second common thickness. The first common thickness may be equal to or different from the second common thickness.

Advantageously, the temperature Tc is high enough to activate the getter material portions 305 during the sealing step. Thus, atoms or molecules of other chemically-active gases 311 present in the second cavity 300b and the third cavity 300c are adsorbed by the getter material portions 305, and the pressure in the second and third cavities 300b, 300c is reduced. However, the noble gas atoms 310 are not adsorbed by the getter material portions 305.

For example, the temperature Tc is higher than 300° C. for a time period comprised between 1 minute and 1 hour, or 15 minutes and 45 minutes, for example equal to 30 minutes.

Sealing using an eutectic alloy or sealing by thermocompression allows releasing the noble gas of the first, second and third portions 105a, 105b, 105c and at the same time activating the getter material portions 305. Alternatively, it is possible to carry out another type of sealing, like for example a metal-metal molecular sealing at low temperature, and perform heating to release the noble gas of the first, second and third portions 105a, 105b, 105c and heating to activate the portions of a getter material 305 during a common step or several subsequent steps. In the case of metal-metal molecular sealing, all of the first, second and third portions 105a, 105b, 105c and of the first, second and third complementary portions 205a, 205b, 205c comprise, for example, essentially titanium, or gold, or copper.

In the case of sealing using an eutectic alloy, the charged material may comprise essentially germanium (respectively aluminum) and the first, second and third complementary portions 205a, 205b, 205c may comprise essentially aluminum. The heating temperature Tc is then higher than or equal to 425° C., or higher than or equal to 450° C.

Still in the case of sealing using an eutectic alloy, the charged material may comprise essentially gold (respectively silicon) and the first, second and third complementary portions 205a, 205b, 205c may comprise essentially silicon (respectively gold). The heating temperature Tc is then higher than or equal to 400° C.

According to another example of sealing using an eutectic alloy, the charged material may comprise essentially gold (respectively tin) and the first, second and third complementary portions 205a, 205b, 205c may comprise essentially tin (respectively gold). The heating temperature Tc is then higher than or equal to 300° C.

A portion of a getter material 305 predominantly comprising titanium is activated at a temperature higher than or equal to 350° C.

In this example, the gyroscope is trapped in the second cavity 300b at a pressure close to the pressure of the enclosure because the second surface 301b has a minimum surface area and by the action of the activated getter material portion 305. For example, the resulting pressure in the second cavity 300b is comprised between 10⁻⁴ mbar (0.01 Pa) and 0.1 mbar (10 Pa), and possibly comprised between 10⁻⁴ mbar (0.01 Pa) and 10⁻³ mbar (0.1 Pa). Hence, the gyroscope can operate properly.

The additional accelerometer is trapped in the third cavity 300c at a pressure strictly higher than the pressure of the enclosure and strictly higher than the pressure of the second cavity 300b. For example, the resulting pressure in the third cavity 300c is comprised between 0.1 mbar (10 Pa) and 10 mbar (10³ Pa).

The accelerometer is trapped in the first cavity 300a at a pressure strictly higher than the pressure of the third cavity 300c. The absence of a portion of a getter material 305 that could adsorb the other gases 311 in the first cavity 300a contributes to the pressure discrepancy between the first cavity 300a and the third cavity 300c. For example, the resulting pressure in the first cavity 300a is comprised between 10 mbar (10³ Pa) and 1 bar (10⁵ Pa). Consequently, in operation, the accelerometer is more damped than the additional accelerometer.

Results are given in Table 1, with regards to a cavity volume equal to 34·10⁶ μm³, a material charged with germanium deposited by IBD, a second layer of aluminum, a heating temperature Tc during the sealing step equal to 425° C., for a time period of 30 minutes, a getter material predominantly comprising titanium activated during the sealing step. In the first column, the surface of the cavity formed by the charged material portion is given with respect to a reference surface S0. The second column indicates the presence (“yes”) or the absence (“no”) of a getter material portion in the cavity. The third column indicates a quality factor in an arbitrary unit as a damping ratio of a resonator placed in the cavity. The fourth column gives the pressure inside the cavity at the end of heating. These results show that three different pressures in three distinct cavities have been obtained with the collective packaging method of the invention.

TABLE 1

| | Getter | | |
|---|---|---|---|
| Wall surface | material | Q | Pressure |
| Sₒ | Yes | 11,000 | 0.1 mbar (10 Pa) |
| S₀ + 37.103 μm² | Yes | 5,000 | 1 mbar (100 Pa) |
| S₀ | No | 800 | 10 mbar (103 Pa) |

The amount of noble gas released by a portion of a material capable of releasing a noble gas contained in the material by heating may be characterized as follows. The known surface potion is hermetically closed under vacuum, for example in a vial. The portion is heated and then cooled down in order to release the noble gas. The pressure Pₐ in the vial is then measured, for example using a friction vacuum gauge. Knowing the volume V_{A} of the vial, it is possible to predict the pressure P_{C} for any cavity volume V_{C}. For example, by application of the ideal gas law, P_{C}=P_{A}V_{A}/V_{C}. The operation may be repeated for different portion surfaces and heating temperatures. A portion surface could then be determined for a given cavity volume, that being so in order to reach a target pressure in the cavity. The pressure in the cavity depends on the portion surface divided by the volume of the cavity, i.e. the ratio of the surface of the portion to the volume of the cavity.

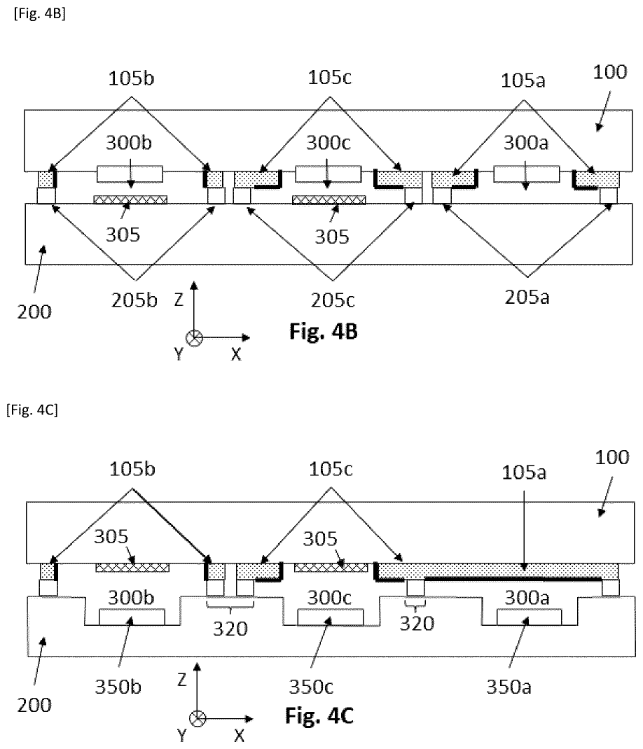

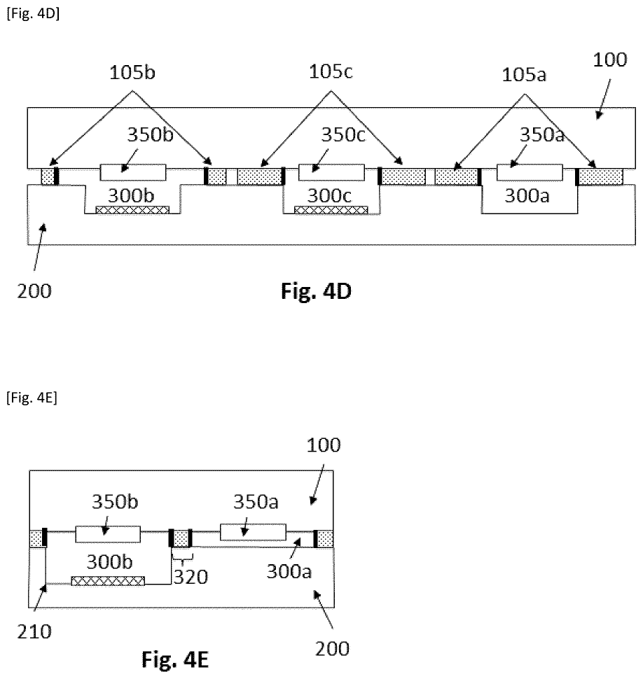

Referring to FIGS. 4A to 4E, several possible configurations at the sealing step, corresponding to the situation of FIG. 3A, will be described in order to illustrate the large number of possibilities offered by the method of the invention. Only differences relating to the conditions that have led to the situation of FIG. 3A will be explicitly described. A person skilled in the art should notice that each of the differences of one configuration could be combined with a difference of another configuration or a feature of the method described with reference to FIGS. 1A, 1B, 2A, 2B, 3A and 3B.

In FIG. 4A, the second layer is also made of a material capable of releasing a noble gas contained in the material by heating. An amount of the noble gas 310 is also released from a surface of each of the first, second and third complementary portions 205a, 205b, 205c inside the respective first, second and third cavities 300a, 300b, 300c, during heating. For example, this variant of the method of the invention allows releasing a larger amount of the noble gas 310 when it is desirable to increase the size of a cavity, or releasing additional gases that cannot be incorporated into the first layer.

In FIG. 4B, we have not etched voids 210 in the cover 200 in order to obtain first, second and third cavities 300a, 300b, 300c with smaller volumes, and thus increase pressure in the first, second and third cavities 300a, 300b, 300c. The packaging structure 1 is also more compact. The third surface 301c is herein equal to the first surface 301a. The pressure in the first cavity 300a is strictly higher than the pressure in the third cavity 300c because of the absence of any portion of a getter material 305 in the first cavity 300a and therefore the presence of other chemically-active gases 311.

In FIG. 4C, the first layer and the second layer have not been etched in a region intended to be an inter-cavity region 320 between the first cavity 300a and the third cavity 300c, thus this inter-cavity region 320 is devoid of any space 315. Thus, a chip comprising the first and third microelectronic devices 350a, 350c is more compact after cutting. In this case, each of the first and third portions 105a, 105c and of the first complementary portions 205a, 205c has, by definition, an end localized in a middle fictive surface of the inter-cavity region 320, orthogonal to the plane (X, Y). The first portion 105a completely covers an upper wall of the first cavity 300a, thus the overflow is maximum. Each of the first, second and third microelectronic devices 350a, 350b, 350c has been formed in a void 210 of the cover 200. The getter material portions 305 have been formed over the substrate 100.

In FIG. 4D, the cover 200 is made of silicon, the charged material comprises essentially gold and sealing consists in sealing using a silicon and gold (AuSi) eutectic alloy. It is then not necessary to form the first, second and third complementary portions 205a, 205b, 205c and the step of FIG. 2A could be omitted. During the affixing step of FIG. 3A, the first, second and third portions 105a, 105b, 105c are brought into direct contact with the second face 202 of the cover 200. Consequently, the first, second and third surfaces 301a, 301b, 301c are substantially equal. The second portion 105b is arranged so as to delimit a surface of the first upper face 101 strictly larger than a surface of the first face 101 delimited by the third portion 105c, the respective voids 210 of the second and third cavities 300b also having identical dimensions. Thus, the volume of the second cavity 300b is strictly larger than the volume of the third cavity 300c and, consequently, the pressure in the second cavity 300b is strictly lower than the volume of the third cavity 300c. The resulting packaging structure 1 is also more compact. Alternatively, the first portion 105a and/or the third portion 105c may be partially suspended over a void 210 in order to define an overflow and thus enlarge the first surface 301a and/or the third surface 301c.

In FIG. 4E, sealing is the same as in FIG. 4D, but another type of sealing could be used. In this case, a first microelectronic device 350a and a second microelectronic device 350b have been formed in and/or over the substrate 100. A void 210 has been etched in the cover 200, intended to form a wall of the second cavity 300b. A surface of the second face 202 of the cover 200 intended to form a wall of the first cavity 300a is protected from etching of the void 210. Thus, the volume of the second cavity 300b is strictly larger than the volume of the first cavity 300a, and the pressure in the second cavity 300b is strictly lower than the pressure in the first cavity 300a, all the more so as the second cavity 300b is devoid of the getter material portion 305. Like in FIG. 4D, the first and second surfaces 301a, 301b are also substantially equal.

Particular embodiments have just been described. Different variants and modifications will appear to a person skilled in the art. In particular, it is possible to form a void both in the cover 200 and in the substrate 100 to obtain, for example, a cavity with a larger volume, and therefore possibly a higher vacuum. It is also possible to form any one of the first, second and third portions 105a, 105b, 105c on sidewalls and/or a bottom of a void 210 of the cover 200 or of the substrate 100 by PVD, IBD or IBS. It is also possible to form some portions among the first, second and third portions 105a, 105b, 105c and the first, second and third complementary portions 205a, 205b, 205c with a charged material and the others with another material, for this purpose, for example, all it needs is to deposit an additional layer after the step of FIG. 1A and/or 2A of a material suited to the sealing step, which does not necessarily contain a noble gas. Thus, for example, the first portion 105a and the second complementary portion 205b may comprise a noble gas, whereas the first complementary portion 205a and the second portion 105b are free of any noble gas. Similarly, it is possible to make the first, second and third microelectronic devices 350a, 350b, 350c indifferently and independently over the substrate 100 or over the cover 200.

The described embodiments relate to the co-integration of accelerometers and gyroscopes, but the invention applies to all types of microelectronics devices having to be packaged, like for example bolometers.

1. A method for manufacturing a packaging structure comprising a first cavity and a second cavity, both hermetic, the method including:
a step of forming over a substrate a first portion of a material capable of releasing a noble gas contained in the material by heating, configured to form a wall of the first cavity,
a step of forming a second portion of the material over the substrate or over a cover, configured to form a wall of the second cavity,
a step of sealing the substrate to the cover so as to form and hermetically close under a common pressure each of the first and second cavities,
a step of heating the first and second cavities to release the noble gas contained in the material,
wherein the first portion and the second portion contribute to sealing of the substrate to the cover during the sealing step,
wherein the wall of the first cavity formed by the first portion has a first surface relative to the volume of the first cavity strictly greater than a second surface of the wall of the second cavity formed by the second portion relative to the volume of the second cavity.

2. The manufacturing method according to claim 1, wherein the sealing step is carried out using an eutectic alloy or by thermocompression, and comprises the heating step.

3. The manufacturing method according to claim 1, wherein the sealing step is performed under a high vacuum at a pressure lower than 0.1 Pa.

4. The manufacturing method according to claim 1, wherein the step of forming the first portion comprises a PVD or IBD type deposition in the presence of a carrier gas of the same nature as the noble gas.

5. The manufacturing method according to claim 1, wherein the second portion is formed over the substrate, at the same time as the first portion is formed.

6. The manufacturing method according to claim 1, further comprising a step of forming a portion of a non-evaporable getter-type material over the substrate or the cover, configured to form a wall of the second cavity, and the getter material portion is activated during the heating step.

7. The manufacturing method according to claim 6, wherein the second portion is formed over the substrate, at the same time as the first portion is formed, wherein the packaging structure further comprising a third hermetic cavity, wherein a third portion of the material is formed over the substrate, at the same time as the first portion and the second portion during the formation step, so that the third portion forms a wall of the third cavity having a third surface strictly comprised between the first surface and the second surface, the third portion contributing to sealing of the substrate to the cover during the sealing step.

8. The manufacturing step according to claim 1, wherein the material is selected from among germanium, gold, an aluminum and silicon alloy and an aluminum and copper alloy.

9. The manufacturing method according to claim 1, further comprising, prior to the sealing step, a step of digging a void in the substrate and/or the cover configured to form walls of the first and/or second cavity.

10. The manufacturing method according to claim 1, further comprising, prior to the sealing step, a step of making a first microelectronic device in and/or over the substrate and/or the cover configured to be trapped in the first cavity, and a step of making a second microelectronic device in and/or over the substrate and/or the cover configured to be trapped in the second cavity.

11. The manufacturing method according to claim 6, further comprising, prior to the sealing step, a step of making an accelerometer in and/or over the substrate and/or the cover configured to be trapped in the first cavity, and a step of making a gyroscope in and/or over the substrate and/or the cover configured to be trapped in the second cavity.

12. The manufacturing method according to claim 7, further comprising, prior to the sealing step, a step of making an accelerometer in and/or over the substrate and/or the cover configured to be trapped in the first cavity, a step of making a gyroscope in and/or over the substrate and/or the cover configured to be trapped in the second cavity, and a step of making an accelerometer in and/or over the substrate and/or the cover configured to be trapped in the third cavity.
